(19) United States
(12) Patent Application Publication
(10) Pub. No.: US 2024/0405104 A1
(43) Pub. Date: Dec. 5, 2024

(54) SEMICONDUCTOR DEVICE

(71) Applicant: SAMSUNG ELECTRONICS CO., LTD., SUWON-SI (KR)

(72) Inventors: Young Gwon KIM, Suwon-si (KR); Myung Gil KANG, Suwon-si (KR); Jin Kyu KIM, Suwon-si (KR); Dong Won KIM, Suwon-si (KR); Beom Jin PARK, Suwon-si (KR)

(21) Appl. No.: 18/648,580

(22) Filed: Apr. 29, 2024

(30) Foreign Application Priority Data
Jun. 2, 2023 (KR) 10-2023-0071388

(51) Int. Cl. H01L 29/735; H01L 29/08; H01L 29/10; H01L 29/40; H01L 29/417

(52) U.S. Cl. CPC H01L 29/735; H01L 29/0808; H01L 29/0821; H01L 29/1008; H01L 29/402; H01L 29/41708

(57) ABSTRACT

A semiconductor device is provided. The semiconductor includes at least one of a well area in a substrate and having a first conductivity-type; impurity-implanted areas in the well, and having a second conductivity-type different from the first conductivity-type and arranged in a first direction, a first fin structure on the impurity-implanted area and having the second conductivity-type, wherein the first fin structure includes first semiconductor patterns and first sacrificial patterns alternately stacked; a first contact on the first fin structure; a first epitaxial pattern on the well area and having the first conductivity-type; and a second contact on the first epitaxial pattern.

### CROSS-REFERENCE TO RELATED APPLICATION

This application claims priority and all the benefits accruing therefrom under 35 U.S.C. 119 from Korean Patent Application No. 10-2023-0071388 filed on Jun. 2, 2023 in the Korean Intellectual Property Office, the contents of which is incorporated herein by reference in its entirety.

### BACKGROUND

### Field

The present disclosure relates to a semiconductor device, and more particularly, to a semiconductor device including a vertical bipolar junction transistor.

### Description of Related Art

A semiconductor device may include an integrated circuit composed of a MOS (Metal Oxide Semiconductor) field effect transistor (FET). As the size and the design rule of the semiconductor device are gradually reduced, the scale down of the MOS field effect transistor is gradually increased. As the size of the MOS field effect transistor decreases, operating characteristics of the semiconductor device may deteriorate. Accordingly, various schemes for forming the semiconductor device with better performance while overcoming limitations due to high integration of semiconductor devices are being studied.

### SUMMARY

A technical purpose to be achieved by the present disclosure is to provide a semiconductor device with improved electrical characteristics.

Various combinations and modifications of the present disclosure that are not mentioned may be understood based on following descriptions, and may be more clearly understood based on embodiments according to the present disclosure. Further, it will be understood that the various embodiments of the present disclosure may be realized using means shown in the claims or combinations thereof.

According to an aspect of the present disclosure, there is provided a semiconductor device including a well area in a substrate, wherein the well area has a first conductivity-type; one or more impurity-implanted areas in the well area, wherein the one or more impurity-implanted areas have a second conductivity-type different from the first conductivity-type, and the one or more impurity-implanted areas are arranged in a first direction, a first fin structure on the one or more impurity-implanted areas, wherein the first fin structure has the second conductivity-type, and wherein the first fin structure includes first semiconductor patterns and first sacrificial patterns alternately stacked; a first contact on the first fin structure; a first epitaxial pattern on the well area, wherein the first epitaxial pattern has the first conductivity-type; and a second contact on the first epitaxial pattern.

According to an aspect of the present disclosure, there is provided a semiconductor device including a well area in an entirety of the substrate, wherein the well area has a first conductivity-type; one or more impurity-implanted areas in the well area, wherein the one or more impurity-implanted areas has a second conductivity-type different from the first conductivity-type; a first fin structure on at least one of the one or more impurity-implanted areas, wherein the first fin structure has the second conductivity-type; and an epitaxial pattern on the well area, wherein the epitaxial pattern has the first conductivity-type.

According to an aspect of the present disclosure, there is provided a semiconductor device including a well area in a substrate and having a first conductivity-type; one or more impurity-implanted areas in the well area, having a second conductivity-type different from the first conductivity-type, wherein the one or more impurity-implanted areas are arranged in a first direction; a first contact on the one or more impurity-implanted area; a second contact on the well area; a first-first metal line electrically connected to the first contact and extending in a second direction intersecting the first direction; a first-second metal line electrically connected to the second contact and extending in the second direction; a second-first metal line electrically connected to the first-first metal line and extending in the first direction; and a second-second metal line electrically connected to the first-second metal line and extending in the first direction.

### BRIEF DESCRIPTION OF DRAWINGS

The above and other aspects and features of the present disclosure will become more apparent by describing in detail illustrative embodiments thereof with reference to the attached drawings, in which:

FIG. 1 is an illustrative top view for illustrating a semiconductor device according to some embodiments;

FIG. 2 is a cross-sectional view taken along A-A′ in FIG. 1;

FIG. 3 is a cross-sectional view taken along B-B′ of FIG. 1;

FIG. 4 is a cross-sectional view taken along C-C′ of FIG. 1;

FIG. 5 is a diagram for illustrating a semiconductor device according to some embodiments;

FIG. 6 to FIG. 8 are diagrams for illustrating a semiconductor device according to some embodiments;

FIG. 9 to FIG. 12 are diagrams for illustrating a semiconductor device according to some embodiments;

FIG. 13 and FIG. 14 are diagrams for illustrating a semiconductor device according to some embodiments;

FIG. 15 to FIG. 20 are diagrams for illustrating a semiconductor device according to some embodiments;

FIG. 21 is a diagram for illustrating a semiconductor device according to some embodiments;

FIG. 22 is a diagram for illustrating a semiconductor device according to some embodiments;

FIG. 23 is a cross-sectional view taken along E-E′ in FIG. 22; and

FIG. 24 is a diagram for illustrating a semiconductor device according to some embodiments.

### DETAILED DESCRIPTIONS

Principles and aspects of the present invention relate to improving semiconductor device performance while reducing device size and design rule. For example, for high integration of the semiconductor device, a multi-bridge channel field effect transistor using a three-dimensional channel can be used. In addition, a structure of a bipolar junction transistor compatible with the multi-bridge channel field effect transistor has been described.

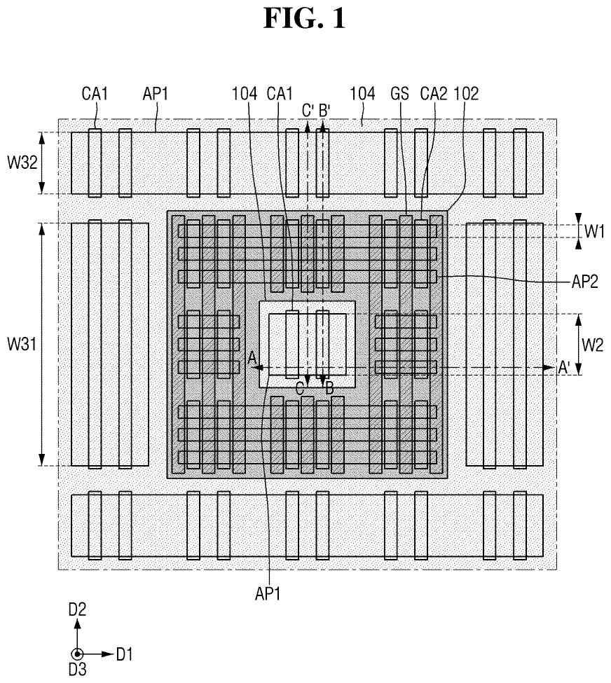

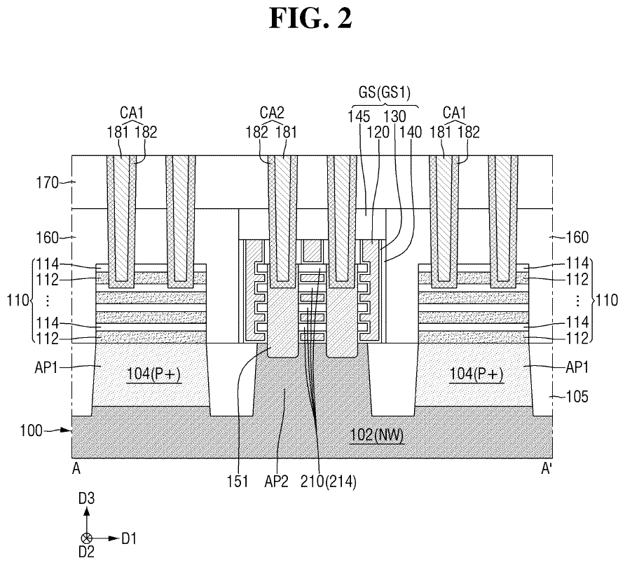

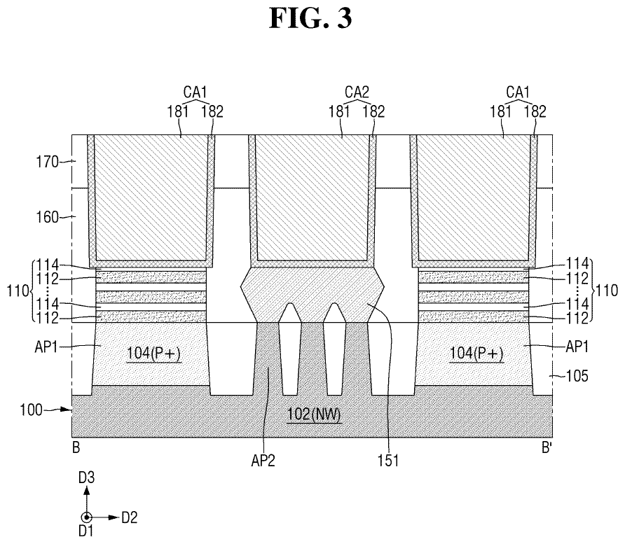

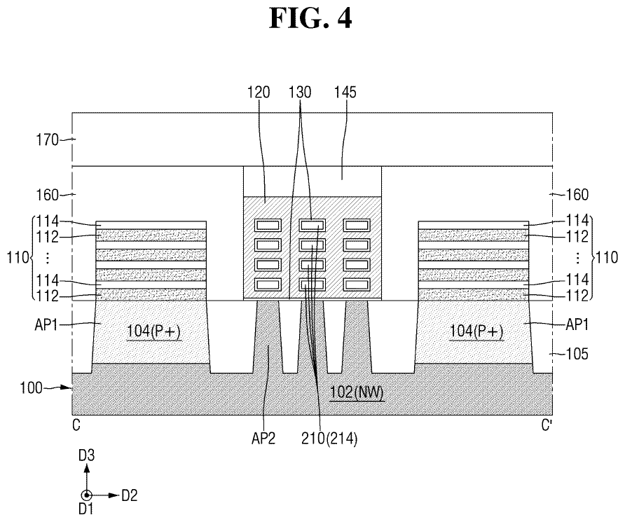

FIG. 1 is an illustrative top view for illustrating a semiconductor device according to some embodiments. FIG. 2 is a cross-sectional view taken along A-A′ in FIG. 1. FIG. 3 is a cross-sectional view taken along B-B′ of FIG. 1. FIG. 4 is a cross-sectional view taken along C-C′ of FIG. 1. FIG. 1 briefly shows the semiconductor device.

Referring to FIG. 1 to FIG. 4, the semiconductor device according to various embodiments includes a substrate 100, a well area (NW) 102, an impurity-implanted area (P+) 104, the element isolation pattern 105, a first active pattern AP1, a second active pattern AP2, a gate structure GS, a first contact CA1, a second contact CA2, a first interlayer insulating film 160, and a second interlayer insulating film 170.

In various embodiments, the substrate 100 may be bulk silicon or a silicon-on-insulator (SOI). The substrate 100 may be a silicon substrate, or may include a material other than silicon, such as silicon germanium, silicon germanium on insulator (SGOI), indium antimonide, lead telluride, indium arsenide, indium phosphide, gallium arsenide, or gallium antimonide. The substrate 100 may include a base substrate and an epitaxial layer formed on the base substrate.

A first direction D1 and a second direction D2 may be parallel to an upper surface of substrate 100. The second direction D2 may intersect the first direction D1. For example, the second direction D2 may be perpendicular to the first direction D1. A third direction D3 may intersect the first direction D1 and the second direction D2. For example, the third direction D3 may be a direction perpendicular to the first direction D1 and the second direction D2, and may be a direction perpendicular to the upper surface of the substrate 100. Hereinafter, an upper surface, an upper portion, a lower surface, a lower portion, and a lower layer are defined based on the third direction D3.

In various embodiments, the well area 102 is disposed in the substrate 100, where the well area 102 can have a first conductivity-type. The well area 102 may be formed by introducing first conductivity-type impurities (e.g., n-type or p-type dopants) into the substrate 100.

In various embodiments, the impurity-implanted area 104 is disposed in the well area 102, where the well area 102 may surround an impurity-implanted area 104. The impurity-implanted area 104 can have a second conductivity-type different from the first conductivity-type. For example, the first conductivity-type may be an N-type, and the second conductivity-type may be a P-type. The well area 102 and the impurity-implanted area 104 may be adjoining and electrically contact each other to form a PN junction. For example, there can be an impurity-implanted area 104 in each of the one or more well areas 102, wherein the one or more impurity-implanted areas have a second conductivity-type different from the first conductivity-type, and the one or more impurity-implanted areas are arranged in a first direction.

In various embodiments, the well area 102 is formed over an entirety of the substrate 100. An area having the second conductivity-type is absent under the well area 102. A lower surface of the well area 102 may coincide with a lower surface of substrate 100, where the well area 102 extends through the substrate.

In various embodiments, the element isolation pattern 105 is formed on the substrate 100, where the element isolation pattern 105 may extend into portions of the substrate. The element isolation pattern 105 may extend from an upper surface of the substrate 100 toward the lower surface thereof, where a lower surface of the element isolation pattern 105 is disposed in the substrate 100 between the upper and lower surfaces. In a plan view (e.g., including the first direction D1 and the second direction D2), the element isolation pattern 105 may be disposed between the impurity-implanted area 104 and the well area 102, where the element isolation pattern 105 can separate portions of the impurity-implanted area 104 from portions of the well area 102. In the plan view, the element isolation pattern 105 may surround the impurity-implanted area 104.

In various embodiments, the element isolation pattern 105 defines the first active pattern AP1 and the second active pattern AP2, where the first active pattern AP1 and the second active pattern AP2 protrude from a lower portion of the substrate 100. The element isolation pattern 105 is disposed on the lower portion of the substrate 100, and interposed between the first active pattern AP1 and the second active pattern AP2. In various embodiments, an upper surface of the first active pattern AP1 and an upper surface of the second active pattern AP2 may be coplanar with an upper surface of the element isolation pattern 105. In another embodiment, the upper surface of the first active pattern AP1 and the upper surface of the second active pattern AP2 may protrude upwardly beyond the upper surface of the element isolation pattern 105.

In various embodiments, the element isolation pattern 105 may include, for example, at least one of silicon oxide, silicon nitride, silicon oxynitride, or combinations thereof.

In various embodiments, the first active pattern AP1 is formed in the impurity-implanted area 104. A lower surface of the element isolation pattern 105 may be positioned at a lower level than a lower surface of the impurity-implanted area 104. The first active pattern AP1 may include the impurity-implanted area 104. The impurity-implanted area 104 may be included in the first active pattern AP1. For example, the first active pattern AP1 may be on and protrude upwardly from the well area 102, where a lower portion of the first active pattern AP1 may include a portion of the well area 102, while an upper portion of the first active pattern AP1 may be formed by the impurity-implanted area 104.

In various embodiments, the second active pattern AP2 is formed from the well area 102, where the second active pattern AP2 may be a portion of the well area 102. The well area 102 may include the second active pattern AP2. The second active pattern AP2 may protrude from the well area 102. The well area 102 may extend along the lower surface of the element isolation pattern 105.

In various embodiments, the first active pattern AP1 has a plate shape (e.g., a rectangular slab), which includes a single active pattern protruding from the lower portion of the substrate 100. The second active patterns AP2 has a fin-shaped pattern, which includes multiple active patterns protruding from the lower portion of the substrate. The second active patterns AP2 extend in an elongate manner in the first direction D1 and are arranged in the second direction D2.

In various embodiments, the first active pattern AP1 disposed inside the well area 102 in a plan view, as shown in FIG. 1, may have a plate shape having a size corresponding to that of the impurity-implanted area 104. In the plan view, the first active pattern AP1 disposed outside the well area 102 may include the first active pattern AP1 disposed on each of upper and lower sides in the second direction D2 of the well area 102 and on each of left and right sides in the first direction D1 thereof. Hereinafter, the upper and lower sides are defined based on the second direction D2, and the left and right sides are defined based on the first direction D1. The first active pattern AP1 disposed on each of the upper, lower, left, and right sides of the well area 102 may have a plate shape having a size corresponding to that of the impurity-implanted area 104 disposed on each of the upper, lower, left, and right sides of the well area 102. The first active pattern AP1 disposed on each of the upper and lower sides of the well area 102 may extend in an elongate manner in the first direction D1. The first active pattern AP1 disposed on each of the left and right sides of the well area 102 may extend in an elongate manner in the second direction D2.

Each of a width W31 in the second direction D2 of the first active pattern AP1 disposed on each of the left and right sides of the well area 102 and a width W2 in the second direction D2 of the first active pattern AP1 disposed inside the well area 102 may be greater than a width W1 in the second direction D2 of the second active pattern AP2. Each of a width W32 in the second direction D2 of the first active pattern AP1 disposed on each of the upper and lower sides of the well area 102 and the width W2 of the first active pattern AP1 disposed inside the well area 102 may be greater than the width W1 in the second direction D2 of the second active pattern AP2.

In various embodiments, a first fin structure 110 may be disposed on the first active pattern AP1. The first fin structure 110 may have a plate shape having a size corresponding to that of the first active pattern AP1. Each of the first fin structures 110 may be disposed on each of the first active patterns AP1.

In various embodiments, the first fin structure 110 may include a plurality of first sacrificial patterns 112 and a plurality of first semiconductor patterns 114 alternately stacked on top of each other, while being disposed on the first active pattern AP1. The first sacrificial patterns 112 and the first semiconductor patterns 114 may be alternately stacked on top of each other along the third direction D3. The first fin structure 110 may have the second conductivity-type. The first fin structure 110 may contain impurities of the second conductivity-type, where n-type or p-type dopants may be included in the first semiconductor patterns 114.

In various embodiments, a second fin structure 210 may be disposed on the second active pattern AP2. Each of the second fin structures 210 may be disposed on each of the second active patterns AP2. In various embodiments, the second fin structure 210 may include a plurality of second semiconductor patterns 214. The plurality of second semiconductor patterns 214 may be spaced apart from the second active pattern AP2 in the third direction D3. The second semiconductor patterns 214 may be spaced apart from each other in the third direction D3.

In various embodiments, each of a width in the second direction D2 of the first semiconductor pattern 114 and a width of the second semiconductor pattern 214 may increase or decrease as each of the first semiconductor pattern 114 and the second semiconductor pattern 214 extends away from the substrate 100. Each of the width in the second direction D2 of the first semiconductor pattern 114 and the width of the second semiconductor pattern 214 may be constant as each of the first semiconductor pattern 114 and the second semiconductor pattern 214 extends away from the substrate 100.

In various embodiments, the first sacrificial pattern 112 may include a different material from that of the first semiconductor pattern 114, where the first sacrificial pattern 112 may be selectively etched relative to the first semiconductor pattern 114 and the second semiconductor pattern 214. The first and second semiconductor patterns 114 and 214 may include the same material as each other, and the first sacrificial pattern 112 may include a different material. For example, the first sacrificial pattern 112 may include silicon germanium (SiGe), and each of the first and second semiconductor patterns 114 and 214 may include silicon (Si).

In various embodiments, the first active pattern AP1 disposed outside the well area 102 may have a plate shape. The first active patterns AP1 respectively disposed on the upper, lower, left, and right sides of the well area 102 may be connected to each other so as to form a shape surrounding the well area 102 in a plan view. The first fin structure 110 disposed outside the well area 102 may also have a single plate shape having a size corresponding to that of one first active patterns AP1.

In various embodiments, the gate structure GS extends in an elongate manner in the second direction D2. The gate structures GS are arranged in the first direction D1. In some embodiments, the plurality of gate structures GS includes a first gate structure GS1 disposed on the well area 102. The gate structure GS is not disposed on the impurity-implanted area 104.

In various embodiments, the first gate structure GS1 is disposed on the second active pattern AP2, where the first gate structure GS1 intersects the second active pattern AP2 and the second fin structure 210. The first gate structure GS1 may surround the second semiconductor pattern 214, where the first gate structure GS1 may be a gate-all-around (GAA) gate structure. The first gate structure GS1 may be disposed on a top surface of the second semiconductor pattern 214 and the element isolation pattern 105. The first gate structure GS1 may cover the top surface of the second semiconductor pattern 214. A first epitaxial pattern 151 may be disposed on a side surface of the first gate structure GS1.

In various embodiments, the gate structure GS may include a gate electrode 120, a gate insulating film 130, a gate spacer 140, and a gate capping pattern 145. The gate structure GS may be an electrically floated dummy gate structure.

In various embodiments, the gate electrode 120 is disposed on the second active pattern AP2. The gate electrode 120 intersects the second active pattern AP2 and the second fin structure 210. The gate electrode 120 may be disposed on the top surface of the second semiconductor pattern 214 and the element isolation pattern 105, where the gate electrode 120 can overlap a portion of each of the element isolation pattern 105 and the second fin structure 210. The gate electrode 120 may cover the second semiconductor pattern 214. The gate electrode 120 may cover the top surface of the second semiconductor pattern 214, and a portion of the gate electrode 120 may be disposed between adjacent pairs of the second semiconductor patterns 214, and between the second active pattern AP2 and the second semiconductor pattern 214 disposed at the lowermost level. In various embodiments, one or more of the gate electrodes 120 may be a dummy gate electrode.

In various embodiments, the gate electrode 120 may include at least one of a metal, a metal alloy, a conductive metal nitride, a metal silicide, a doped semiconductor material, a conductive metal oxide, or a conductive metal oxynitride.

In various embodiments, the gate insulating film 130 extends along a portion of the upper surface of the element isolation pattern 105 and an upper surface of the second active pattern AP2, where the upper surface of the element isolation pattern 105 and the upper surface of the second active pattern AP2 can be coplanar. The gate insulating film 130 is disposed along a profile of the second semiconductor pattern 214. The gate electrode 120 is disposed on the gate insulating film 130. The gate insulating film 130 is disposed between the gate electrode 120 and the second semiconductor pattern 214, where the gate insulating film 130 separates the gate electrode 120 from the second semiconductor pattern 214. A portion of the gate insulating film 130 may be disposed between adjacent ones of the second semiconductor patterns 214 and between the second active pattern AP2 and the second semiconductor pattern 214 disposed at the lowermost level.

In various embodiments, the gate insulating film 130 may be embodied as a single film, or may include an interface film and a high dielectric constant insulating film.

In various embodiments, the gate insulating film 130 may include silicon oxide, silicon-germanium oxide, germanium oxide, silicon oxynitride, silicon nitride, or a high-k material having a higher dielectric constant than that of silicon oxide.

In various embodiments, the gate spacer 140 is disposed on a sidewall of the gate electrode 120. The gate spacer 140 may not be disposed between the second active pattern AP2 and the second semiconductor pattern 214 disposed at the lowest level and between adjacent ones of the second semiconductor patterns 214. An inner wall of the gate spacer 140 may face the gate electrode 120. The gate insulating film 130 may extend along the inner wall of the gate spacer 140, where the gate insulating film 130 may separate the gate spacer 140 from the gate electrode 120. The gate insulating film 130 may contact the gate spacer 140.

In various embodiments, the gate spacer 140 may include, for example, at least one of silicon nitride (SiN), silicon oxynitride (SiON), silicon oxide (SiO₂), silicon oxycarbonitride (SiOCN), silicon boron nitride (SiBN), silicon oxyboronitride (SiOBN), silicon oxycarbide (SiOC), or combinations thereof.

In various embodiments, the gate capping pattern 145 may be disposed on the gate electrode 120, the gate insulating film 130, and the gate spacer 140. Alternatively, the gate capping pattern 145 may be disposed between the gate spacers 140.

In various embodiments, the gate capping pattern 145 may include, for example, at least one of silicon nitride (SiN), silicon oxynitride (SiON), silicon carbonitride (SiCN), silicon oxycarbonitride (SiOCN), or combinations thereof.

In various embodiments, the first contact CA1 is connected to the first fin structure 110 and the second contact CA2 is connected to the first epitaxial pattern 151.

In various embodiments, the first epitaxial pattern 151 is disposed on the second active pattern AP2. The first epitaxial pattern 151 may be electrically connected to the second semiconductor pattern 214, where the first epitaxial pattern 151 may physically contact the second semiconductor pattern 214. The first epitaxial pattern 151 may extend through the second fin structure 210, and into the second active pattern AP2, so as to be electrically connected to the second active pattern AP2. The first epitaxial pattern 151 may be disposed between the first gate structures GS1 adjacent to each other in the first direction D1. For example, the first epitaxial pattern 151 may be disposed on each of both opposing sides surface of the first gate structure GS1, but may not be disposed on a side surface of the first gate structure GS1 disposed on the element isolation pattern 105.

In various embodiments, the first epitaxial pattern 151 may be formed from the second active pattern AP2 through an epitaxial growth process. The first epitaxial pattern 151 may have the second conductivity-type, where the first epitaxial pattern 151 may include impurities of the second conductivity-type (e.g., n-type dopants or p-type dopants).

In various embodiments, the first interlayer insulating film 160 is disposed on the substrate 100, where the first interlayer insulating film 160 may cover the substrate 100, the element isolation pattern 105, the first fin structure 110, and the first epitaxial pattern 151. The first interlayer insulating film 160 may be laterally adjacent to the gate capping pattern 145. An upper surface of the first interlayer insulating film 160 may not cover an upper surface of the gate capping pattern 145, such that the gate capping pattern 145 can be exposed. For example, the upper surface of the first interlayer insulating film 160 may be coplanar with the upper surface of the gate capping pattern 145.

In various embodiments, the second interlayer insulating film 170 may be disposed on the first interlayer insulating film 160, where the second interlayer insulating film 170 may cover the upper surface of the gate capping pattern 145 and the upper surface of the adjoining first interlayer insulating film 160.

In various embodiments, the first interlayer insulating film 160 may include, for example, at least one of silicon oxide, silicon nitride, silicon oxynitride, or a low dielectric constant material. The second interlayer insulating film 170 may include at least one of silicon oxide, silicon nitride, silicon oxynitride, or a low dielectric constant material. The first interlayer insulating film 160 and the second interlayer insulating film 170 may be made of the same material or different materials.

In various embodiments, a plurality of first contacts CA1 are disposed on the first active pattern AP1. The first contacts CA1 may extend through the first and second interlayer insulating films 160 and 170, and are electrically connected to the first fin structure 110. The first contact CA1 may extend through a portion of the first fin structure 110, such that a lower surface of the first contact CA1 may be disposed in the first fin structure 110, where, for example, the first contact CA1 may be electrically connected to the first semiconductor pattern 114.

In various embodiments, a plurality of second contacts CA2 are disposed on the second active pattern AP2. The second contacts CA2 may be disposed between the first gate structures GS1 adjacent to each other in the first direction D1. The second contacts CA2 extend through the first and second interlayer insulating films 160 and 170, such that a lower surface thereof is disposed on the first epitaxial pattern 151.

Each of the first and second contacts CA1 and CA2 may include a barrier metal layer 182 and a metal layer 181. The metal layer 181 may extend through the first and second interlayer insulating films 160 and 170. The barrier metal layer 182 may extend along a side surface and a lower surface of the metal layer 181, where the barrier metal layer 182 is between the metal layer 181 and the first and second interlayer insulating films 160 and 170.

In various embodiments, the barrier metal layer 182 may include, for example, a conductive metal nitride such as titanium nitride, tantalum nitride, or tungsten nitride. The metal layer 181 may include, for example, a metal material such as cobalt (Co), titanium (Ti), tantalum (Ta), ruthenium (Ru), tungsten (W), or cobalt tungsten phosphorus (CoWP).

In various embodiments, the impurity-implanted area 104, the first active pattern AP1, and the first contact CA1 may constitute an emitter of a vertical bipolar junction transistor. The well area 102, the second active pattern AP2, the first gate structure GS1, the first epitaxial pattern 151, and the second contact CA2 may constitute a base of the vertical bipolar junction transistor. A collector of the vertical bipolar junction transistor may be omitted. That is, the semiconductor device according to various embodiments may include the vertical bipolar junction transistor including the base and the emitter and free of the collector. The emitter may be implemented in place of the collector, where an emitter replaces the collector with the emitter located in what would otherwise be a collector area. The bases and the emitters may be alternately arranged with each other. Accordingly, an area of the PN junction may be increased, so that the current density may be increased, and the leakage current may be reduced, compared to a case in which the collector is present.

Furthermore, in the semiconductor device according to various embodiments, the first active pattern AP1 of the impurity-implanted area 104 may be of a planer type in which an upper surface thereof extends in a first direction and is flat. Accordingly, an area of the PN junction, which the impurity-implanted area 104 and the well area 102 constitute, may increase, compared to a case where the impurity-implanted area 104 includes a plurality of second active patterns AP2, as the well area 102 does. In addition, a contact area between the first fin structure 110 and the first contact CA1 may increase, compared to a case where the impurity-implanted area 104 includes a plurality of second active patterns AP2, as the well area 102 does. Accordingly, current density may increase, and the leakage current may decrease. Accordingly, the semiconductor device with improved electrical performance may be provided.

In the semiconductor device according to various embodiments, a power line supplying power to the semiconductor device may be disposed on the lower surface of the substrate 100. The power line may be connected to the first and second contacts CA1 and CA2 via a conductive pattern buried in the substrate 100. The substrate 100 may be etched upwardly from the lower surface and become thinner, where a thickness in the third direction D3 may be reduced. For example, the substrate 100 may be etched, so that only the first active pattern AP1 and the second active pattern AP2 remain. Accordingly, a role of the collector may be insignificant. That is, even when the emitter is disposed instead of the collector, according to some embodiments, performance of the vertical bipolar junction transistor may be maintained.

In various embodiments, a signal line supplying an operation signal of the semiconductor device may be disposed on the upper surface of the substrate 100. In various embodiments, the signal line supplying the operation signal of the semiconductor device may be disposed on the lower surface of the substrate 100. The vertical bipolar junction transistor according to some embodiments may include a lower transistor and an upper transistor. Each of the first and second fin structures 110 and 210 may include a lower fin structure and an upper fin structure. The first epitaxial pattern 151 may include a lower epitaxial pattern and an upper epitaxial pattern disposed on the lower epitaxial pattern. A separation layer (for example, first interlayer insulating film 160) may be formed between the lower fin structure and the upper fin structure and between the lower epitaxial pattern and the upper epitaxial pattern.

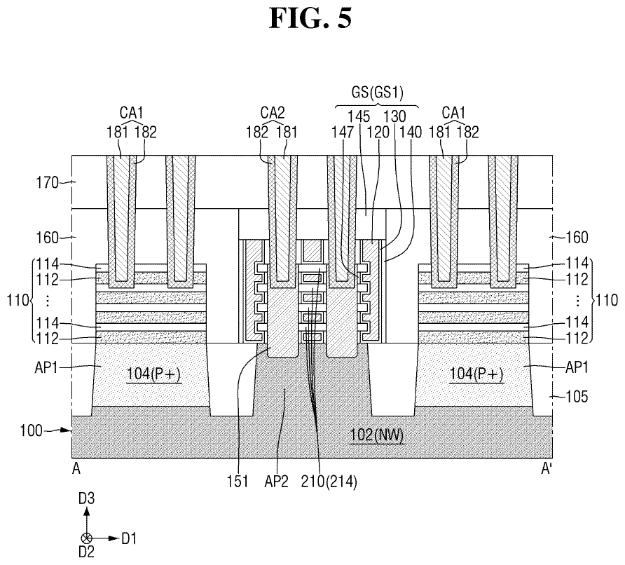

FIG. 5 is a diagram for illustrating a semiconductor device according to some embodiments. For reference, FIG. 5 is a cross-sectional view taken along A-A′ in FIG. 1. For convenience of description, differences thereof from the descriptions as set forth above with reference to FIG. 1 to FIG. 4 will be mainly described.

Referring to FIG. 5, in the semiconductor device according to some embodiments, the gate structure GS further includes an inner spacer 147.

In various embodiments, the inner spacer 147 is disposed between adjacent pairs of the second semiconductor patterns 214, and between the second active pattern AP2 and the second semiconductor pattern 214 disposed at the lowermost level. The inner spacer 147 may contact a portion of the gate insulating film 130 between adjacent ones of the second semiconductor patterns 214, and between the second active pattern AP2 and the second semiconductor pattern 214 disposed at the lowermost level. The inner spacer 147 may define a portion of the first epitaxial pattern 151. The inner spacer 147 may separate the first epitaxial pattern 151 from the gate insulating film 130.

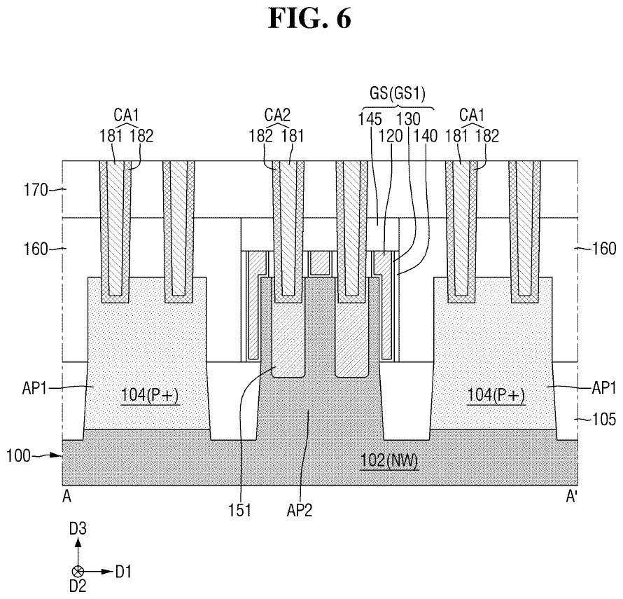

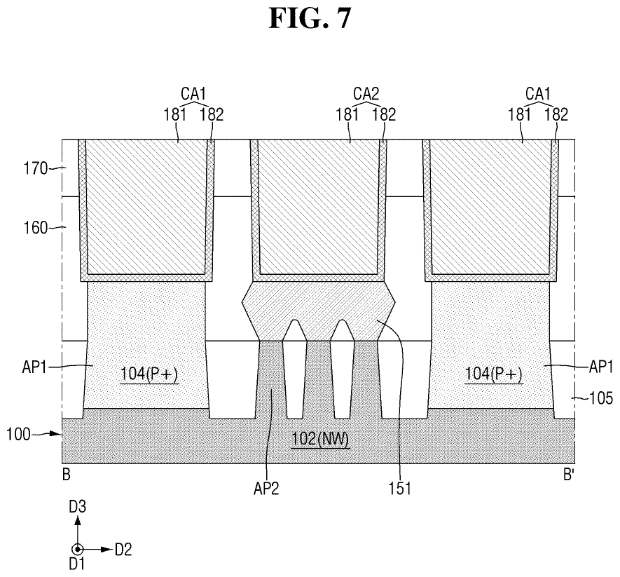

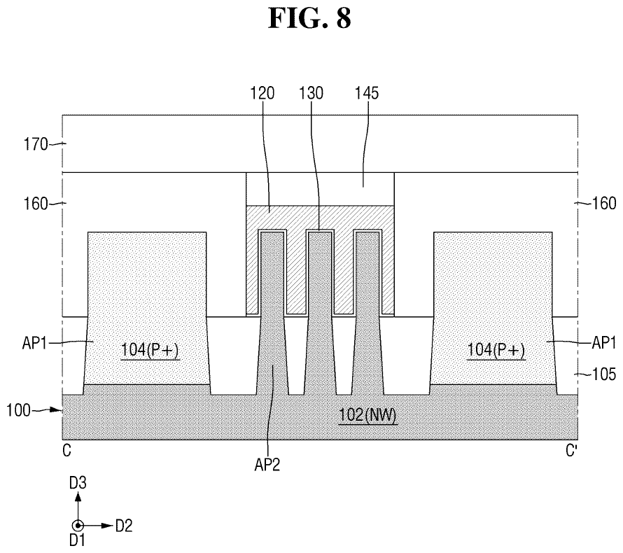

FIG. 6 to FIG. 8 are diagrams for illustrating a semiconductor device according to some embodiments. For reference, FIG. 6 is a cross-sectional view taken along A-A′ in FIG. 1. FIG. 7 is a cross-sectional view taken along B-B′ of FIG. 1. FIG. 8 is a cross-sectional view taken along C-C′ of FIG. 1. For convenience of description, differences thereof from the descriptions as set forth above with reference to FIG. 1 to FIG. 4 will be mainly described.

Referring to FIG. 6 to FIG. 8, in the semiconductor device according to various embodiments, the fin structure (for example, each of the first and second semiconductor patterns 114 and 214 of FIG. 1 to FIG. 4) is not disposed on each of the first and second active patterns AP1 and AP2. Each of the first and second active patterns AP1 and AP2 may be a fin-shaped pattern protruding upwardly beyond the upper surface of the element isolation pattern 105, where an upper surface of the first and second active patterns AP1 and AP2 are above the upper surface of the element isolation pattern 105. The element isolation pattern 105 may cover a portion of a sidewall of the first active pattern AP1 and a portion of a sidewall of the second active pattern AP2. The first interlayer insulating film 160 may be disposed on the element isolation pattern 105 and cover a portion of a sidewall of the first active pattern AP1 and a portion of a sidewall of the second active pattern AP2 above the element isolation pattern 105.

In various embodiments, the first gate structure GS1 may be disposed on a top surface of the second active pattern AP2 and the element isolation pattern 105. The first gate structure GS1 may cover the top surface of the second active pattern AP2. The gate electrode 120 may be disposed on the top surface of the second active pattern AP2 and the element isolation pattern 105. The gate electrode 120 may cover the top surface of the second active pattern AP2.

In various embodiments, the first epitaxial pattern 151 is disposed on the second active pattern AP2. The first epitaxial pattern 151 is electrically connected to the second active pattern AP2. The second contact CA2 is connected to the first epitaxial pattern 151.

In various embodiments, the first contact CA1 may extend through the first and second interlayer insulating films 160 and 170, so as to be electrically connected to the first active pattern AP1. For example, the first contact CA1 may extend through a portion of the first active pattern AP1, such that a lower surface of the first contact CA1 may be disposed in the first active pattern AP1.

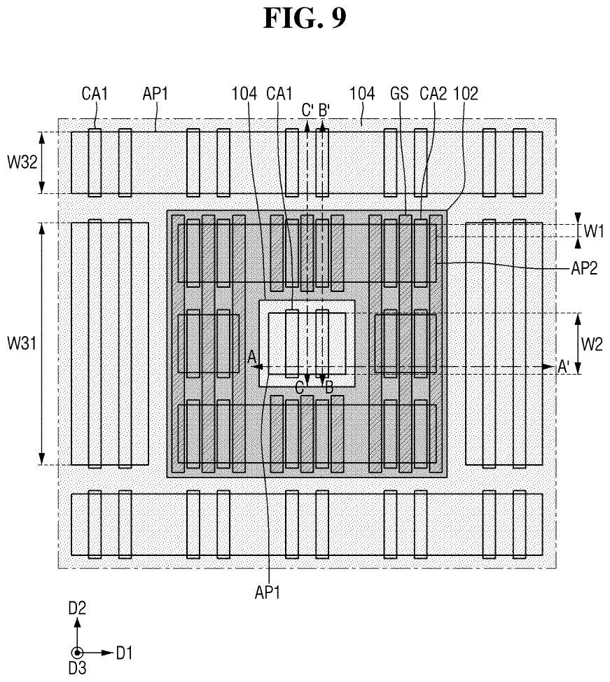

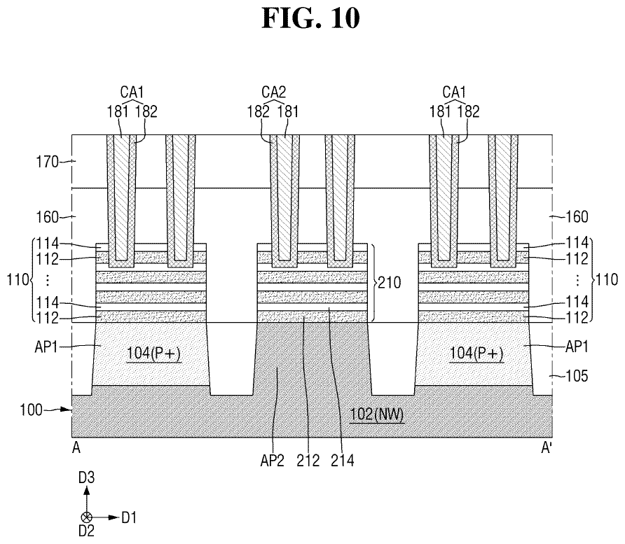

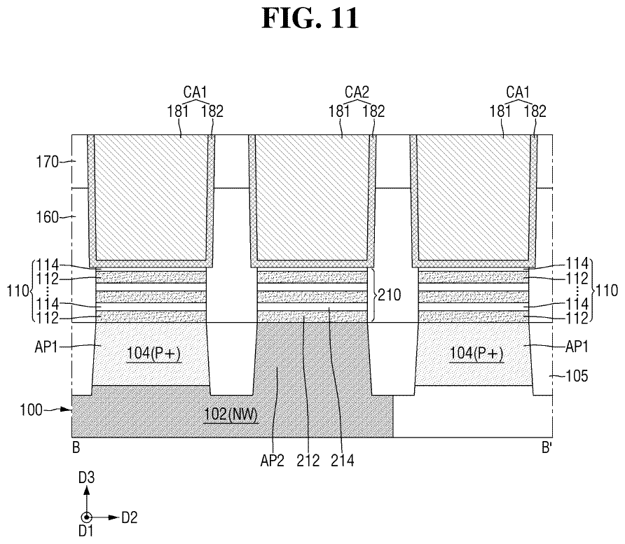

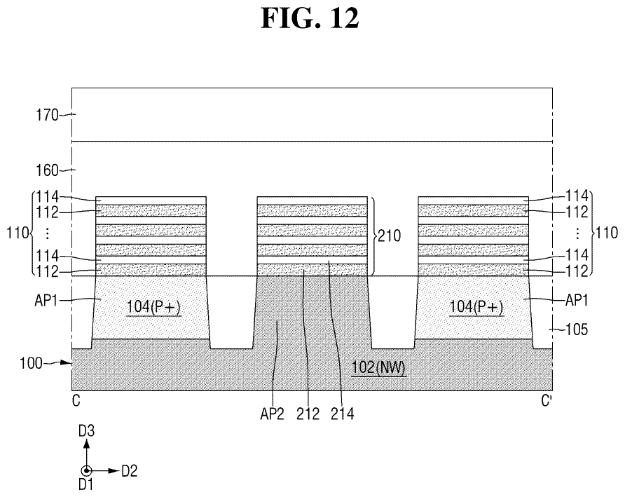

FIG. 9 to FIG. 12 are diagrams for illustrating a semiconductor device according to various embodiments. For reference, FIG. 10 is a cross-sectional view taken along A-A′ in FIG. 9. FIG. 11 is a cross-sectional view taken along B-B′ in FIG. 10. FIG. 12 is a cross-sectional view taken along C-C′ of FIG. 9. In FIG. 9, the element isolation pattern 105, etc. are not shown. For convenience of description, differences thereof from the descriptions as set forth above with reference to FIG. 1 to FIG. 4 will be mainly described.

Referring to FIG. 9 to FIG. 12, in the semiconductor device according to some embodiments, the second active pattern AP2 has a plate shape.

In various embodiments, one second active pattern AP2 may be disposed on each of an upper side, a lower side, a left side, and a right side of the impurity-implanted area 104 disposed inside the well area 102. The second active pattern AP2 disposed on each of an upper side, a lower side, a left side, and a right side of the impurity-implanted area 104 disposed inside the well area 102 may have a plate shape having a size corresponding to that of a portion of the well area 102 disposed on each of upper, lower, left, and right sides of the impurity-implanted area 104 disposed inside the well area 102. The second active pattern AP2 disposed on each of the upper and lower sides of the impurity-implanted area 104 disposed inside the well area 102 may extend in an elongate manner in the first direction D1. The second active pattern AP2 disposed on each of the left and right sides of the impurity-implanted area 104 disposed inside the well area 102 may extend in an elongate manner in the second direction D2.

In various embodiments, each of the second fin structures 210 has a plate shape having a size corresponding to that of each of the second active patterns AP2. The second fin structure 210 may include a plurality of second sacrificial patterns 212 and a plurality of second semiconductor patterns 214 alternately stacked on top of each other, while being disposed on the second active pattern AP2. The second sacrificial patterns 212 and the second semiconductor patterns 214 may be alternately stacked on top of each other along the third direction D3. The second fin structure 210 may have the first conductivity-type. The second fin structure 210 may contain impurities of the first conductivity-type, where n-type or p-type dopants may be included in the first semiconductor patterns 114.

In various embodiments, the second sacrificial pattern 212 may include a material different from that of the second semiconductor pattern 214, where the second sacrificial pattern 212 may be selectively etched relative to the first semiconductor pattern 114 and the second semiconductor pattern 214. The first and second sacrificial patterns 112 and 212 may include the same material, and the first and second semiconductor patterns 114 and 214 may include the same material. The first and second sacrificial patterns 112 and 212 may include a different material. For example, each of the first and second sacrificial patterns 112 and 212 may include silicon germanium (SiGe), and each of the first and second semiconductor patterns 114 and 214 may include silicon (Si).

In various embodiments, the second active pattern AP2 may have a plate shape. The second active patterns AP2 on the upper, lower, left, and right sides of the impurity-implanted area 104, itself disposed inside the well area 102, may be connected to each other to form a shape (e.g., squared torus) surrounding the implanted area 104 disposed inside the well area 102 in a plan view. The second fin structure 210 may have a plate shape having a size corresponding to that of one second active pattern AP2.

The semiconductor device according to some embodiments does not include the gate structure (GS in FIG. 1 to FIG. 4).

In various embodiments, the second contact CA2 is connected to the second fin structure 210. The first interlayer insulating film 160 may cover the substrate 100, the element isolation pattern 105, the first fin structure 110, and the second fin structure 210. The second contact CA2 may extend through the first and second interlayer insulating films 160 and 170, so as to be electrically connected to the second fin structure 210. The second contact CA2 may extend through a portion of the second fin structure 210, such that a lower surface of the second contact CA2 may be disposed in the second fin structure 210. For example, the second contact CA2 may be electrically connected to the second semiconductor pattern 214.

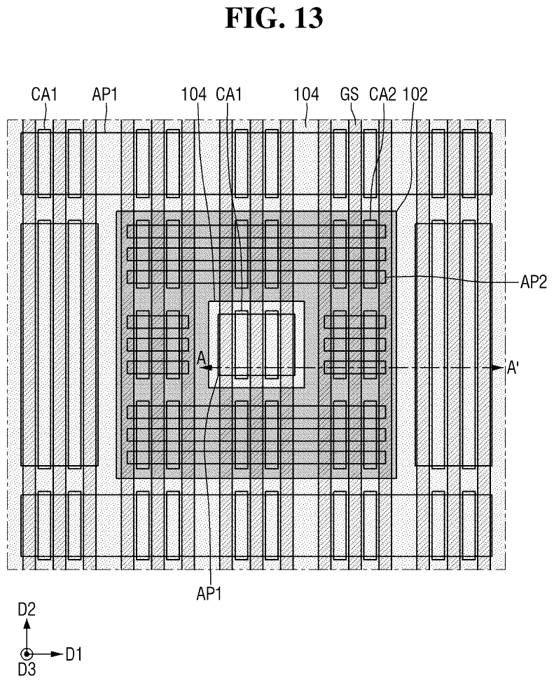

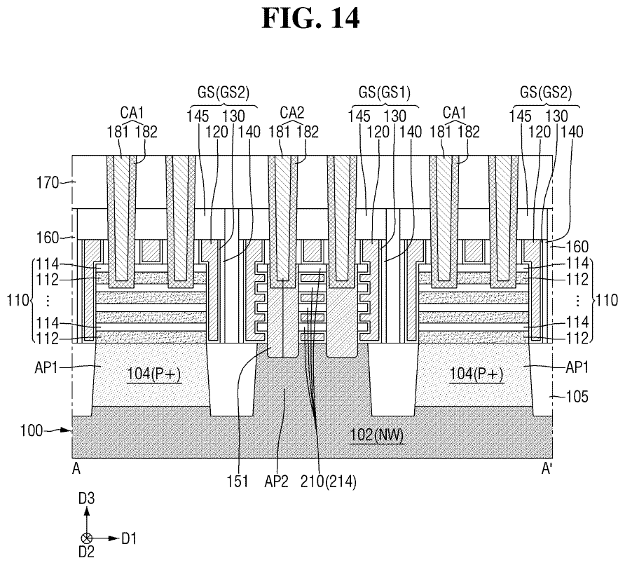

FIG. 13 and FIG. 14 are diagrams for illustrating a semiconductor device according to various embodiments. For reference, FIG. 14 is a cross-sectional view taken along A-A′ in FIG. 13. FIG. 13 briefly shows the semiconductor device, while the element isolation pattern 105, etc. are not shown. For convenience of description, differences thereof from the descriptions as set forth above with reference to FIG. 1 to FIG. 4 will be mainly described.

Referring to FIG. 13 and FIG. 14, in the semiconductor device according to various embodiments, the gate structure GS includes the first gate structure GS1 disposed on the well area 102 and a second gate structure GS2 disposed on the impurity-implanted area 104.

In various embodiments, the second gate structure GS2 is disposed on the impurity-implanted area 104, where the second gate structure GS2 is disposed on the first active pattern AP1. The second gate structure GS2 intersects the first active pattern AP1 and the first fin structure 110. The second gate structure GS2 may be disposed on a top surface of the first fin structure 110 and the element isolation pattern 105. The second gate structure GS2 may cover the top surface of the first fin structure 110.

In various embodiments, the gate electrode 120 is disposed on the first active pattern AP1. The gate electrode 120 intersects the first active pattern AP1. The gate electrode 120 may be disposed on the top surface of the first fin structure 110 and the element isolation pattern 105, where the gate electrode 120 can overlap a portion of each of the element isolation pattern 105 and the first fin structure 110. The gate electrode 120 may cover the top surface of the first fin structure 110.

In various embodiments, the gate insulating film 130 is disposed between the gate electrode 120 and the first fin structure 110 and between the gate electrode 120 and the element isolation pattern 105. The gate insulating film 130 can cover opposite sidewalls and a bottom surface of the gate electrode 120.

In various embodiments, the first contact CA1 may be disposed between portions of the second gate structure GS2 adjacent to each other in the first direction D1.

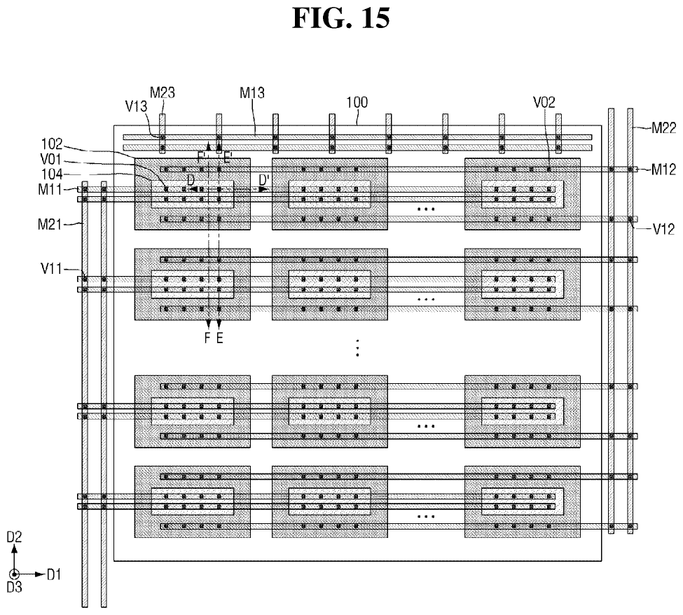

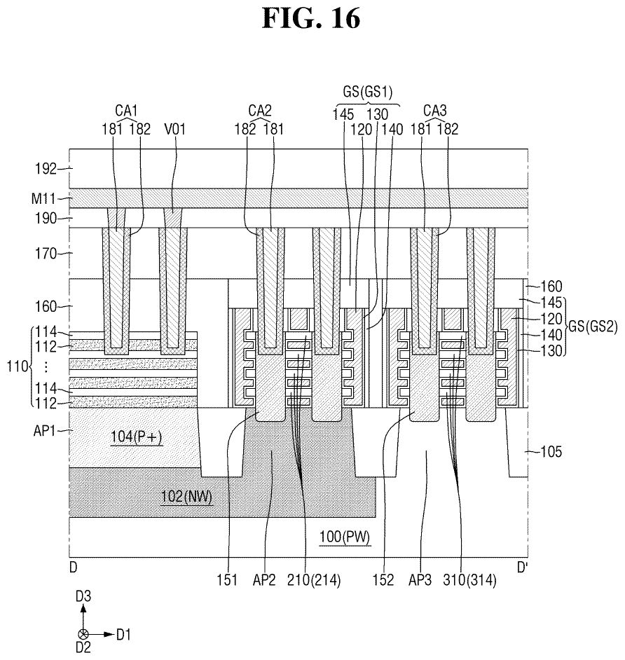

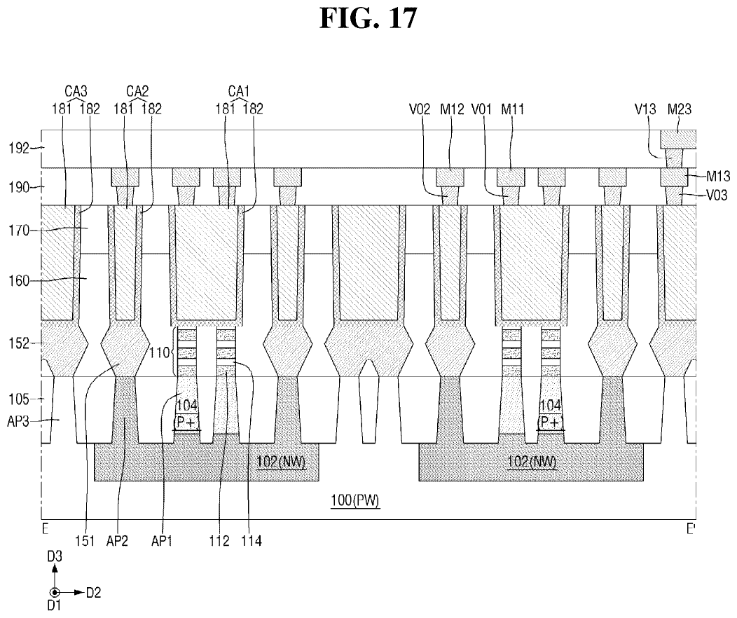

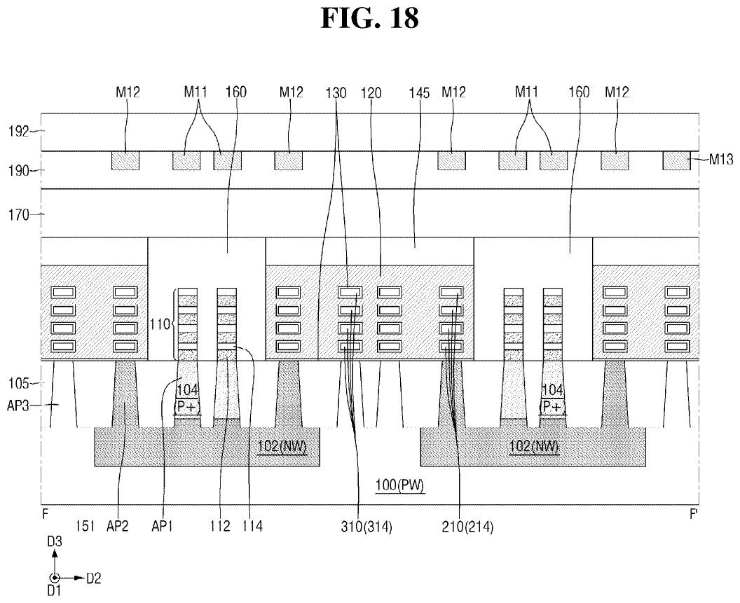

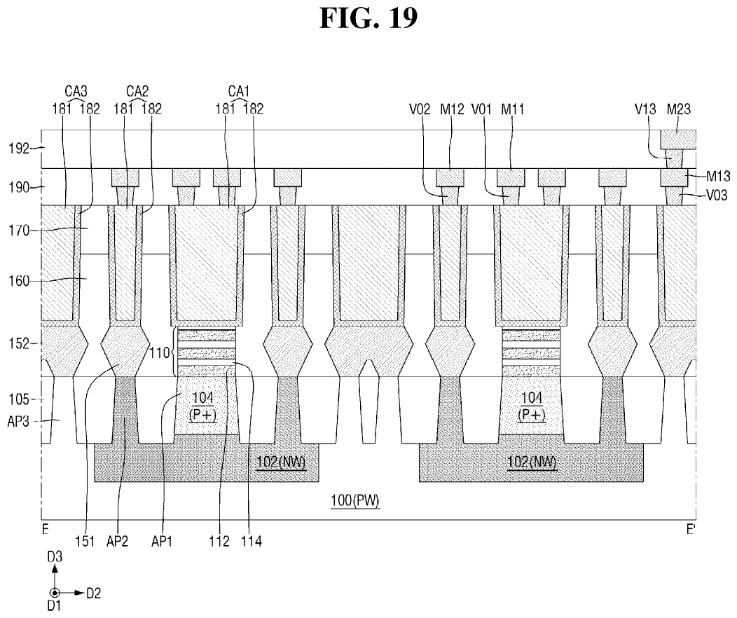

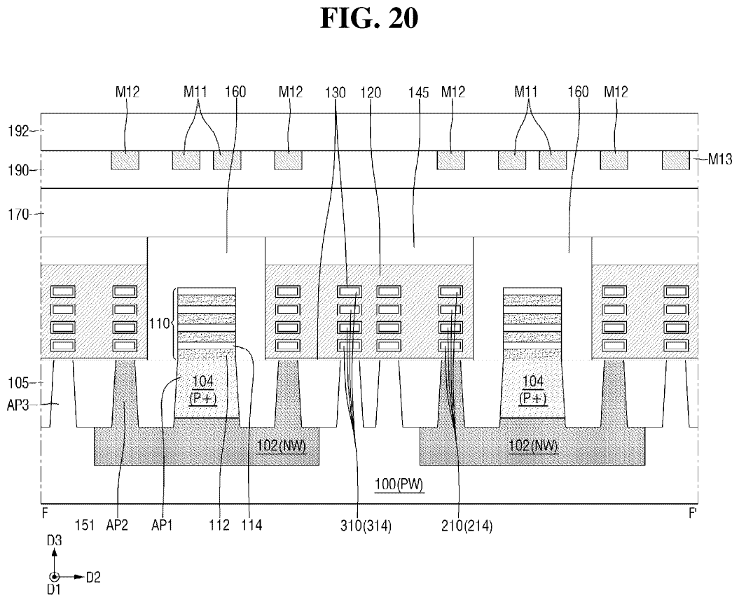

FIG. 15 to FIG. 20 are diagrams for illustrating a semiconductor device according to some embodiments. For reference, FIG. 16 is a cross-sectional view taken along D-D′ of FIG. 15. FIG. 17 and FIG. 19 are cross-sectional views taken along E-E′ in FIG. 15. FIG. 18 and FIG. 20 are cross-sectional views taken along F-F′ in FIG. 15. FIG. 15 briefly shows the semiconductor device, while the element isolation pattern 105, etc. are not shown. For convenience of description, differences thereof from the descriptions as set forth above with reference to FIG. 1 to FIG. 4 will be mainly described.

Referring to FIG. 15 to FIG. 18, in the semiconductor device according to some embodiments, the well areas 102 are arranged in the first direction D1 and the second direction D2 and are disposed in the substrate 100. The impurity-implanted areas 104 are arranged in the first direction D1 and the second direction D2 and are disposed in the substrate 100. Each impurity-implanted area 104 is disposed in each well area 102. For example, there can be one or more impurity-implanted areas 104 in each of the well areas 102, wherein the one or more impurity-implanted areas have a second conductivity-type different from the first conductivity-type, and the one or more impurity-implanted areas are arranged in a first direction.

In various embodiments, the substrate 100 has the second conductivity-type. The well area 102 having the first conductivity-type may be disposed in a portion of the substrate 100. In a plan view, the well area 102 may surround the impurity-implanted area 104.

In various embodiments, the element isolation pattern 105 defines the first to third active patterns AP1, AP2, and AP3, where the third active pattern AP3 can be different from the first and second active patterns AP1 and AP2. The element isolation pattern 105 may be disposed between adjacent ones of the first to third active patterns AP1, AP2, and AP3. An upper surface of the third active pattern AP3 may be coplanar with the upper surface of the element isolation pattern 105. In various embodiments, the upper surface of the third active pattern AP3 may protrude upwardly beyond the upper surface of the element isolation pattern 105.

The third active pattern AP3 may protrude from a lower portion of the substrate 100, where the third active pattern AP3 may be a portion of the substrate 100. The substrate 100 may include the third active pattern AP3. The third active patterns AP3 may extend in an elongate manner in the first direction D1 and may be arranged in the second direction D2.

In various embodiments, a third fin structure 310, as shown in FIG. 16, may be disposed on the third active pattern AP3. A third fin structure 310 may be disposed on each third active pattern AP3. The third fin structure 310 may include a plurality of third semiconductor patterns 314, where the plurality of third semiconductor patterns 314 may be spaced apart from the third active pattern AP3 in the third direction D3. The third semiconductor patterns 314 may be spaced apart from each other in the third direction D3. A width in the second direction D2 of the third semiconductor pattern 314 may increase or decrease as the third semiconductor pattern 314 extends away from the substrate 100. In various embodiments, the width in the second direction D2 of the third semiconductor pattern 314 may be constant, as the third semiconductor pattern 314 extends away from the substrate 100.

In various embodiments, the first to third semiconductor patterns 114, 214, and 314 may include the same material as each other. For example, the first sacrificial pattern 112 may include silicon germanium (SiGe), and the first to third semiconductor patterns 114, 214, and 314 may include silicon (Si), where the materials may be selectively etched relative to each other.

In various embodiments, the first active patterns AP1 may extend in an elongate manner in the first direction D1 and may be arranged in the second direction D2. Each of the first fin structures 110 is disposed on each of the first active patterns AP1.

In various embodiments, the gate structure GS includes the first gate structure GS1 disposed on the well area 102 and a third gate structure GS3 disposed on the substrate 100.

In various embodiments, the third gate structure GS3 is disposed on the third active pattern AP3, where the third gate structure GS3 intersects the third active pattern AP3 and the third fin structure 310. The third gate structure GS3 may surround the third semiconductor pattern 314, where the third gate structure GS3 may be a gate-all-around (GAA) gate structure. The third gate structure GS3 may be disposed on a top surface of the third semiconductor pattern 314 and the element isolation pattern 105. The third gate structure GS3 may cover the top surface of the third semiconductor pattern 314. A second epitaxial pattern 152 may be disposed on a side surface of the third gate structure GS3.

In various embodiments, the gate electrode 120 is disposed on the third active pattern AP3, where the gate electrode 120 intersects the third active pattern AP3 and the third fin structure 310. The gate electrode 120 may be disposed on the top surface of the third semiconductor pattern 314 and the element isolation pattern 105, where the gate electrode 120 can overlap a portion of each of the element isolation pattern 105 and the third fin structure 310. The gate electrode 120 may surround the third semiconductor pattern 314. The gate electrode 120 may cover the top surface of the third semiconductor pattern 314. A portion of the gate electrode 120 may be disposed between adjacent pairs of the third semiconductor patterns 314, and between the third active pattern AP3 and the third semiconductor pattern 314 disposed at the lowermost level.

In various embodiments, the gate insulating film 130 extends along a portion of the upper surface of the element isolation pattern 105 and along an upper surface of the third active pattern AP3. The gate insulating film 130 is disposed along a profile of the third semiconductor pattern 314. The gate insulating film 130 is disposed between the gate electrode 120 and the third semiconductor pattern 314, where the gate insulating film 130 separates the gate electrode 120 from the third semiconductor pattern 314. A portion of the gate insulating film 130 may be disposed between adjacent ones of the third semiconductor patterns 314 and between the third active pattern AP3 and the third semiconductor pattern 314 disposed at the lowermost level. The gate insulating film 130 can cover opposite sidewalls and a bottom surface of the gate electrode 120.

In various embodiments, the gate spacer 140 may not be disposed between the third active pattern AP3 and the lowest third semiconductor pattern 314, and between adjacent ones of the third semiconductor patterns 314.

In various embodiments, at least one of the first gate structure GS1 and the third gate structure GS3 may further include the inner spacer 147, as described using FIG. 5. In some embodiments, each of the first active pattern AP1 and the second active pattern AP2 may be a fin-shaped pattern, as described using FIG. 6 to FIG. 8. The third active pattern AP3 may be a fin-shaped pattern. The fin structure (for example, the third fin structure 310 of FIGS. 15 to 18) may not be disposed on the third active pattern AP3. In various embodiments, the second active pattern AP2 and the second fin structure 210 may be substantially the same as the second active pattern AP2 and the second fin structure 210, as described using FIG. 9 to FIG. 12, respectively. In various embodiments, each of the third active pattern AP3 and the third fin structure 310 may have a plate shape (e.g., rectangular), like each of the second active pattern AP2 and the second fin structure 210, as described using FIG. 9 to FIG. 12. In various embodiments, the gate structure GS may further include the first gate structure GS1, as described using FIG. 13 and FIG. 14.

In various embodiments, a third contact CA3 is connected to the second epitaxial pattern 152.

In various embodiments, the second epitaxial pattern 152 is disposed on the third active pattern AP3, where the second epitaxial pattern 152 may be electrically connected to the third semiconductor pattern 314. The second epitaxial pattern 152 may contact the third semiconductor pattern 314. The second epitaxial pattern 152 may extend through the third fin structure 310, so as to be electrically connected to the third active pattern AP3. The second epitaxial pattern 152 may be disposed between adjacent ones of the third gate structures GS3 in the first direction D1. For example, the second epitaxial pattern 152 may be disposed on each of both opposing side surfaces of the third gate structure GS3, but may not be disposed on a sides surface of the third gate structure GS3 disposed on the element isolation pattern 105.

In various embodiments, the second epitaxial pattern 152 may be formed from the third active pattern AP3 in an epitaxial growth process. The second epitaxial pattern 152 may have the second conductivity-type (e.g., n-type or p-type). The second epitaxial pattern 152 may contain impurities of the second conductivity-type, for example, an n-type dopant or a p-type dopant.

In various embodiments, a plurality of third contacts CA3 are disposed on the third active pattern AP3. The third contact CA3 may be disposed between adjacent ones in the first direction D1 of the third gate structures GS3. The third contact CA3 may extend through the first and second interlayer insulating films 160 and 170, such that a lower surface thereof is disposed on the second epitaxial pattern 152. The third contact CA3 may include the barrier metal layer 182 and the metal layer 181.

In various embodiments, the substrate 100, the third active pattern AP3, the second epitaxial pattern 152, the third gate structure GS3, and the third contact CA3 may constitute the collector of the vertical bipolar junction transistor. The semiconductor device according to some embodiments may include the vertical bipolar junction transistors, each including an emitter, base, and collector, wherein the vertical bipolar junction transistors are arranged in the first direction D1 and the second direction D2.

When a power line that supplies power to the semiconductor device is disposed on the lower surface of the substrate 100, the substrate 100 is etched upwardly from the lower surface thereof, such that a thickness of the well area 102 in the third direction D3 may be reduced, and leakage current may increase. However, in the semiconductor device according to some embodiments, the well areas 102 has an array structure and the impurity-implanted areas 104 has an array structure so that the thickness of the well area 102 and the impurity-implanted area 104 may be adjusted. Accordingly, the semiconductor device with improved electrical performance may be provided.

In the semiconductor device according to various embodiments, a first-first metal line M11, as shown in FIG. 16, is electrically connected to the first contact CA1, where the first-first metal line M11 can be electrically connected to the metal layer 181 of the first contact CA1 by a first contact via V01. A first-second metal line M12, as shown in FIG. 17, is electrically connected to the second contact CA2, where the first-second metal line M12 can be electrically connected to the metal layer 181 of the second contact CA2 by a second contact via V02. A first-third metal line M13 is electrically connected to the third contact CA3, where the first-third metal line M13 can be electrically connected to the metal layer 181 of the third contact CA3 by a third contact via V03. A second-first metal line M21 is electrically connected to the first-first metal line M11. A second-second metal line M22 is electrically connected to the first-second metal line M12. A second-third metal line M23 is electrically connected to the first-third metal line M13.

In various embodiments, a third interlayer insulating film 190 may be disposed on the second interlayer insulating film 170, and the first to third contacts CA1 to CA3. A fourth interlayer insulating film 192 may be disposed on the third interlayer insulating film 190. Each of the third interlayer insulating film 190 and the fourth interlayer insulating film 192 may include, for example, at least one of silicon oxide, silicon nitride, silicon oxynitride, or a low-k material.

In various embodiments, a first contact via V01, a second contact via V02, a third contact via V03, the first-first metal line M11, the first-second metal line M12 and the first-third metal line M13 may be disposed in the third interlayer insulating film 190. The first-first metal line M11, the first-second metal line M12, and the first-third metal line M13 may extend in an elongate manner in the first direction D1. The first contact via V01 may electrically connect the first contact CA1 and the first-first metal line M11 to each other. The second contact via V02 may electrically connect the second contact CA2 and the first-second metal line M12 to each other. The third contact via V03 may electrically connect the third contact CA3 and the first-third metal line M13 to each other.

In various embodiments, a first via V11, a second via V12, a third via V13, the second-first metal line M21, the second-second metal line M22, and the second-third metal line M23 may be disposed in the fourth interlayer insulating film 192. The second-first metal line M21, the second-second metal line M22, and the second-third metal line M23 may extend in an elongate manner in the second direction D2. The first via V11 may electrically connect the first-first metal line M11 and the second-first metal line M21 to each other. The second via V12 may electrically connect the first-second metal line M12 and the second-second metal line M22 to each other. The third via V13 may electrically connect the first-third metal line M13 and the second-third metal line M23 to each other. Accordingly, emitters may be connected to each other, bases may be connected to each other, and collectors may be connected to each other.

Referring to FIG. 19 and FIG. 20, in a semiconductor device according to some embodiments, each of the first active pattern AP1 and the first fin structure 110 may have a plate shape. The first active pattern AP1 and the first fin structure 110 may be substantially the same as the first active pattern AP1 and the first fin structure 110 as described using FIG. 1 to FIG. 4, respectively.

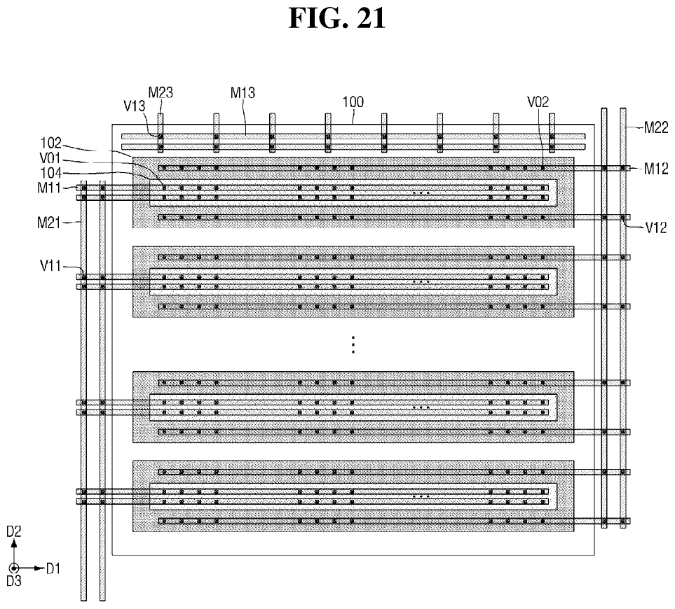

FIG. 21 is a diagram for illustrating a semiconductor device according to some embodiments. For convenience of description, differences thereof from the descriptions as set forth above with reference to FIG. 15 to FIG. 20 will be mainly described.

Referring to FIG. 21, in the semiconductor device according to some embodiments, the well areas 102 are arranged in the second direction D2 and the impurity-implanted areas 104 are arranged in the second direction D2. Each impurity-implanted area 104 is disposed in each well area 102. The well area 102 and the impurity-implanted area 104 extend in an elongate manner in the first direction D1.

In various embodiments, the first active pattern AP1 and the first fin structure 110 may be substantially the same as the first active pattern AP1 and the first fin structure 110 as described using FIGS. 15 to 18, respectively. In some embodiments, the first active pattern AP1 and the first fin structure 110 may be substantially the same as the first active pattern AP1 and the first fin structure 110 as described using FIGS. 19 and 20, respectively.

The semiconductor device according to some embodiments may include the vertical bipolar junction transistors, each including an emitter, a base, and a collector, wherein the vertical bipolar junction transistors are arranged in the second direction D2.

The arrangement of the well areas 102 and the arrangement of the impurity-implanted areas 104 may vary as long as the design rule is not violated. The well areas 102 may be arranged in various forms, wherein each impurity-implanted area 104 may be disposed in each well area 102.

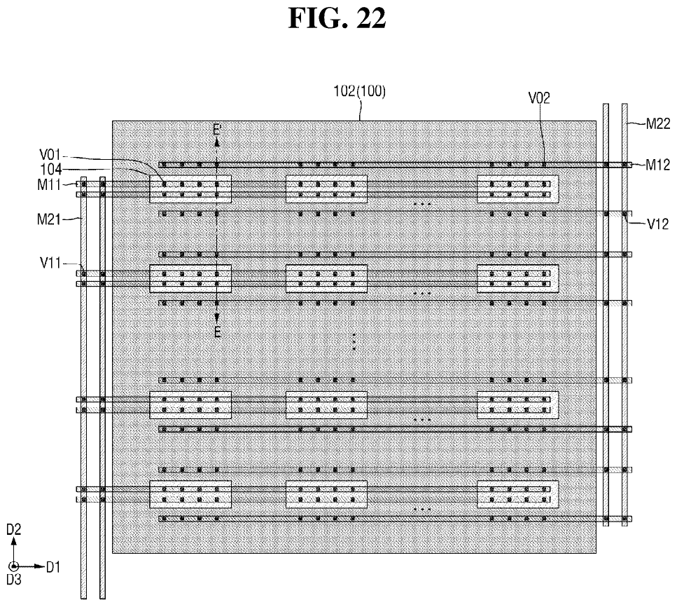

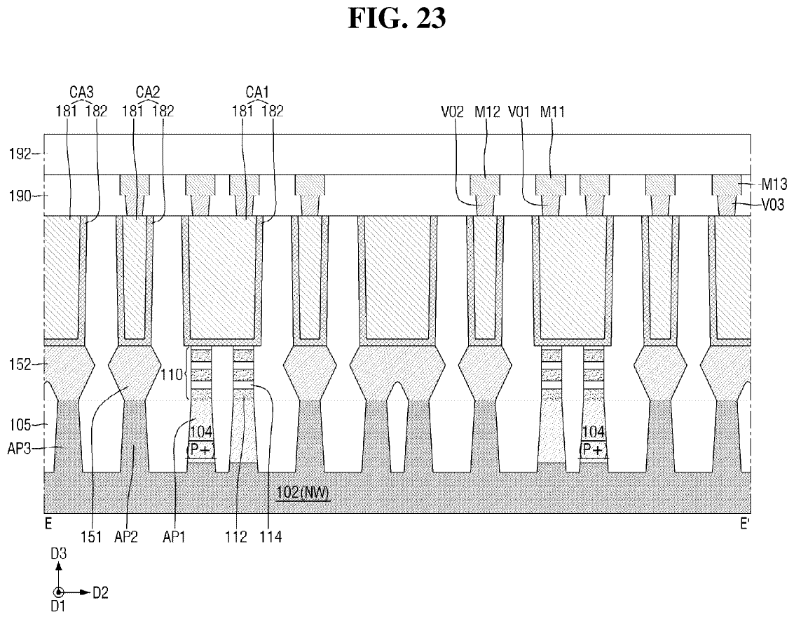

FIG. 22 is a diagram for illustrating a semiconductor device according to some embodiments. FIG. 23 is a cross-sectional view taken along E-E′ in FIG. 22. For convenience of description, differences thereof from the descriptions as set forth above with reference to FIG. 15 to FIG. 20 will be mainly described.

Referring to FIGS. 22 and 23, in the semiconductor device according to some embodiments, the impurity-implanted areas 104 are arranged in the first direction D1 and the second direction D2, and are disposed in the well area 102. The well area 102 is disposed over an entirety of the substrate 100. The third active pattern AP3, the third fin structure 310, the third contact CA3, the third contact via V03, the first-third metal line M13, the third via V13, and the second-third metal line M23 of FIG. 15 to FIG. 20 may be omitted.

In various embodiments, the semiconductor device according to various embodiments may include the vertical bipolar junction transistors, each including an emitter and a base, and omitting the collector, wherein the vertical bipolar junction transistors are arranged in the first direction D1 and the second direction D2.

In various embodiments, the first active pattern AP1 and the first fin structure 110 may be substantially the same as the first active pattern AP1 and the first fin structure 110 as described using FIGS. 15 to 18, respectively. In various embodiments, the first active pattern AP1 and the first fin structure 110 may be substantially the same as the first active pattern AP1 and the first fin structure 110, as described using FIGS. 19 and 20, respectively.

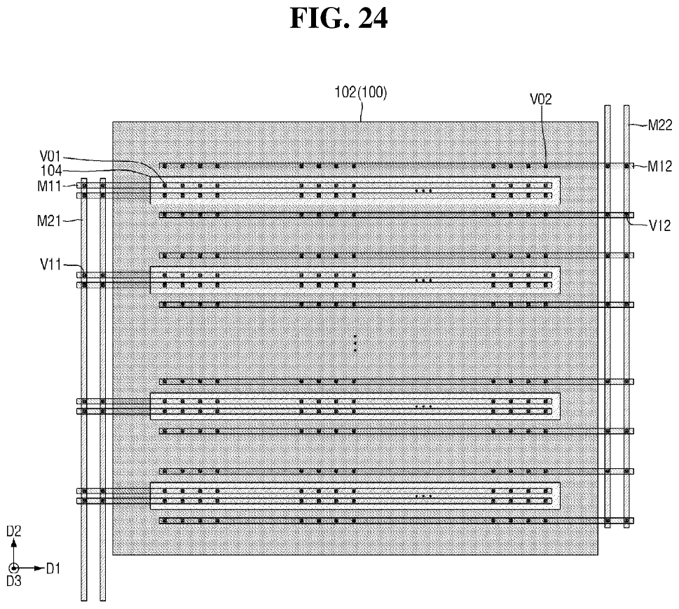

FIG. 24 is a diagram for illustrating a semiconductor device according to some embodiments. For convenience of description, differences thereof from the descriptions as set forth above with reference to FIG. 22 to FIG. 23 will be mainly described.

Referring to FIG. 24, in the semiconductor device according to some embodiments, the impurity-implanted areas 104 are arranged in the second direction D2. The impurity-implanted area 104 extends in an elongate manner in the first direction D1.

In various embodiments, the first active pattern AP1 and the first fin structure 110 may be substantially the same as the first active pattern AP1 and the first fin structure 110 as described using FIGS. 15 to 18, respectively. In various embodiments, the first active pattern AP1 and the first fin structure 110 may be substantially the same as the first active pattern AP1 and the first fin structure 110 as described using FIGS. 19 and 20, respectively.

In various embodiments, the semiconductor device according to some embodiments may include the vertical bipolar junction transistors, each including an emitter and a base, and omitting the collector, wherein the vertical bipolar junction transistors are arranged in the second direction D2.

In various embodiments, the arrangement of the impurity-implanted areas 104 may vary as long as it does not violate design rules. The impurity-implanted areas 104 may be arranged in various forms.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A semiconductor device comprising:
a well area in a substrate, wherein the well area has a first conductivity-type;
one or more impurity-implanted areas in the well area, wherein the one or more impurity-implanted areas have a second conductivity-type different from the first conductivity-type, and the one or more impurity-implanted areas are arranged in a first direction,
a first fin structure on the one or more impurity-implanted areas, wherein the first fin structure has the second conductivity-type, and wherein the first fin structure includes first semiconductor patterns and first sacrificial patterns alternately stacked;
a first contact on the first fin structure;
a first epitaxial pattern on the well area, wherein the first epitaxial pattern has the first conductivity-type; and
a second contact on the first epitaxial pattern.

2. The semiconductor device of claim 1, further comprising:
a first-first metal line electrically connected to the first contact, wherein the first-first metal line extends in a second direction intersecting the first direction;
a first-second metal line electrically connected to the second contact, wherein the first-second metal line extends in the second direction;
a second-first metal line electrically connected to the first-first metal line, wherein the second-first metal line extends in the first direction; and
a second-second metal line electrically connected to the first-second metal line, wherein the second-second metal line extends in the first direction.

3. The semiconductor device of claim 1, wherein the substrate has the second conductivity-type,
wherein one or more well areas are arranged along the first direction, and
wherein each of the one or more impurity-implanted areas is disposed in each of the one or more well areas.

4. The semiconductor device of claim 1, wherein the plurality of one or more impurity-implanted areas are arranged along a second direction intersecting the first direction.

5. The semiconductor device of claim 4, wherein the substrate has the second conductivity-type,
wherein one or more well areas and the impurity-implanted areas are arranged along the first direction and the second direction, and
wherein each of the one or more impurity-implanted areas is disposed in each of the one or more well areas.

6. The semiconductor device of claim 1, further comprising:
a second epitaxial pattern on the substrate, wherein the second epitaxial pattern has the second conductivity-type; and
a third contact on the second epitaxial pattern,
wherein the substrate has the second conductivity-type.

7. The semiconductor device of claim 1, further comprising a plurality of gate structures, wherein one of the plurality of gate structures is on each of a plurality of well areas, wherein the gate structures extend in the first direction, and are arranged in a second direction intersecting the first direction,
wherein the first epitaxial pattern is disposed between adjacent ones of the gate structures.

8. The semiconductor device of claim 1, further comprising a second fin structure on the well area, wherein the second fin structure includes a plurality of second semiconductor patterns,
wherein the first epitaxial pattern is connected to the plurality of second semiconductor patterns.

9. The semiconductor device of claim 1, wherein the well area is in an entirety of the substrate.

10. A semiconductor device comprising:
a well area in an entirety of the substrate, wherein the well area has a first conductivity-type;
one or more impurity-implanted areas in the well area, wherein the one or more impurity-implanted areas has a second conductivity-type different from the first conductivity-type;
a first fin structure on at least one of the one or more impurity-implanted areas, wherein the first fin structure has the second conductivity-type; and
an epitaxial pattern on the well area, wherein the epitaxial pattern has the first conductivity-type.

11. The semiconductor device of claim 10, wherein the one or more impurity-implanted areas are arranged along a first direction and extend in a second direction intersecting the first direction, and
wherein the first fin structure is on each of the one or more impurity-implanted areas.

12. The semiconductor device of claim 10, wherein the one or more impurity-implanted areas are arranged along a first direction and a second direction intersecting the first direction, and
wherein the first fin structure is disposed on each of the one or more impurity-implanted areas.

13. The semiconductor device of claim 10, wherein the first fin structure includes first semiconductor patterns and first sacrificial patterns alternately stacked on the one or more impurity-implanted areas.

14. The semiconductor device of claim 10, further comprising a plurality of gate structures on the first fin structure, wherein the gate structures extend in a first direction, and are arranged in a second direction intersecting the first direction.

15. The semiconductor device of claim 10, further comprising:
a second fin structure on the well area, wherein the second fin structure includes a plurality of second semiconductor patterns spaced apart from the well area; and
a plurality of gate structures on the well area, wherein the gate structures extend in a first direction, and are arranged in a second direction intersecting the first direction,
wherein the epitaxial pattern is disposed between adjacent ones of the plurality of gate structures and is connected to the plurality of second semiconductor patterns.

16. The semiconductor device of claim 15, wherein the plurality of gate structures each include:
a gate electrode on the well area and surrounding the plurality of second semiconductor patterns; and
a gate spacer on a side surface of the gate electrode.

17. The semiconductor device of claim 16, wherein the gate structures further include an inner spacer on a portion of a side surface of the gate electrode, wherein the portion is disposed between the well area and the second semiconductor pattern adjacent to the well area, and between adjacent ones of the second semiconductor patterns.

18. A semiconductor device comprising:
a well area in a substrate and having a first conductivity-type;
one or more impurity-implanted areas in the well area, having a second conductivity-type different from the first conductivity-type, wherein the one or more impurity-implanted areas are arranged in a first direction;
a first contact on the one or more impurity-implanted area;
a second contact on the well area;
a first-first metal line electrically connected to the first contact and extending in a second direction intersecting the first direction;
a first-second metal line electrically connected to the second contact and extending in the second direction;
a second-first metal line electrically connected to the first-first metal line and extending in the first direction; and
a second-second metal line electrically connected to the first-second metal line and extending in the first direction.

19. The semiconductor device of claim 18, further comprising:
a third contact on the substrate;
a first-third metal line electrically connected to the third contact and extending in the second direction; and
a second-third metal line connected to the first-third metal line and extending in the first direction,
wherein the substrate has the second conductivity-type.

20. The semiconductor device of claim 18, further comprising:
a first fin structure on each of the one or more impurity-implanted area, wherein the first fin structure has the second conductivity-type, wherein the first fin structure includes first semiconductor patterns and first sacrificial patterns alternately stacked;
a second fin structure on the well area, wherein the second fin structure has the first conductivity-type, and wherein the second fin structure includes second semiconductor patterns and second sacrificial patterns alternately stacked,
wherein the first contact is connected to the first fin structure, and
wherein the second contact is connected to the second fin structure.
